(19) United States
(12) Patent Application Publication
(10) Pub. No.: US 2020/0024763 A1
(43) Pub. Date: Jan. 23, 2020

(54) ELECTROFORM VAPOR CHAMBER INTEGRATED THERMAL MODULE INTO PCB LAYOUT DESIGN

(71) Applicant: MICROSOFT TECHNOLOGY LICENSING, LLC, Redmond, WA (US)

(72) Inventors: Bo DAN, Redmond, WA (US); Robert Ullman MYERS, Kirkland, WA (US); Han LI, Sammamish, WA (US); James Hao-An Chen LIN, Seattle, WA (US); Andrew HILL, Redmond, WA (US)

(73) Assignee: MICROSOFT TECHNOLOGY LICENSING, LLC, Redmond, WA (US)

(21) Appl. No.: 16/043,098

(22) Filed: Jul. 23, 2018

(51) Int. Cl. C25D 1/02; G06F 17/50

(52) U.S. Cl. CPC C25D 1/02; H05K 7/1427; G06F 17/5081

(57) ABSTRACT

Systems and methods are described, and one method includes storing a PCB dimension, a vapor chamber (VC) case configuration, a package height of a heat-generating (HG) device, a component data identifying a height of a component, and a layout configuration data indicating locations for the HG device and the component. Upon determining the component location is an interfering location, the VC case configuration data is updated to indicate an inner clearance perimeter for the VC case, surrounding the interfering location. Electroforming forms the VC, for thermal coupling to the HG device, having a VC case with rimless, seamless outer peripheral surfaces aligned and facing according to the VC case outer perimeter, and other rimless surfaces aligned and facing, relative to the clearance perimeter, to form a clearance.

### TECHNICAL FIELD

This disclosure relates generally to devices and methods for thermal management of printed circuit board (PCB) mounted devices and, more particularly, to vapor chamber heat spreaders for PCB mounted arrangements of electronic devices and peripheral components.

### BACKGROUND

A vapor chamber (VC) heat spreader includes a metal casing enclosing a hermetically sealed chamber. A working fluid, such as water, is in the chamber. One surface of the casing is thermally coupled to, e.g., contacts, a surface of a heat generating (HG) electronic device. One example is a microprocessor. Another surface of the casing can be thermally coupled to a cooling structure, such as cooling fins, other head spreaders, an external housing or other enclosure, or can be insulated by air.

The HG device, when powered up, heats an immediate region of the metal casing, which heats the working fluid in the adjacent portion of the chamber. When the temperature of the fluid exceeds its vaporization temperature, some of the fluid changes to vapor. The vapor moves toward the cooler region of the chamber. At that region, the vapor cools to less than the fluid's condensation temperature, causing it to condense back to a liquid. The liquid travels back, e.g., through a wick within the chamber, to the chamber region near the HG device, and the process repeats. The continuous loop of vaporization and condensation provides efficient transfer of heat from the HG device to the cooling region.

VC metal cases can be constructed of two pieces of sheet metal, one being an upper sheet and the other being a lower sheet, each having cooperatively formed vertical (upturned or downturned) peripheral walls. A wick, e.g., a metal mesh, can be placed within the cap or bowl of one of the metal sheets, and the respective peripheral walls compressed. The compression produces a diffusion bonding of the peripheral walls, forming a rimmed, seamed metal shell enclosing a chamber. The working fluid, e.g., water, is injected into the chamber, then the chamber is vacuumed and sealed.

To avoid leakage of the diffusion bonded rims, the width of the rim area must be significant. This creates several technical issues. One is that it reduces the chamber volume obtainable from a given perimeter area. In other words, the VC device occupies substantially more area than the VC it implements. Another technical issue with the rim is that it increases the VC weight.

The rim area directly reduces the available PCB area for mounting components that are taller than the HG device. This is due to the HG device height generally establishing the spacing between the support surface of the PCB and the bottom surface of the rimmed VC device. Therefore, any components taller than the HG device, which can be referred to as “excess height components,” must be installed outside of the outer rim of the rimmed VC device. This causes further technical issues, as it necessitates locating the excess height components in locations that may be far from ideal, for example, with respect to signal paths.

Disclosed methods and apparatuses, described in greater detail in paragraphs that follow and the referenced drawings, provide technical solutions to the above-described technical problems, and provide further technical benefits and advantages.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

An example disclosed method for vapor chamber thermal control can include storing a VC configuration data that can define, at least in part, a particular contour or shape of the VC case, including a VC case outer perimeter and a clearance perimeter, at least partially surrounding a clearance location within the VC case outer perimeter, and can include electroforming a seamless case surrounding a chamber, the seamless case having an external surface that includes a top surface and a bottom surface, spaced apart by a height, a rimless outer peripheral surface extending along the case outer perimeter, and a rimless clearance surface, extending along the clearance perimeter from the top surface to the bottom surface, at least partially surrounding the clearance location.

Another example disclosed method for vapor chamber thermal control can include storing a plurality of VC case configurations, each VC case configuration including a corresponding case outer perimeter and case clearance perimeter, wherein the case outer perimeter can define, at least in part, an alignment and a facing direction of a rimless, seamless outer lateral peripheral surface of the VC case. The clearance perimeter can define an alignment and facing direction of other rimless, seamless lateral peripheral surfaces of the VC case that form a clearance surface. This example disclosed method can include receiving a configuration data defining, at least in part, a PCB, a PCB location for an HG device, a package height for the HG device, and a PCB location and a component height for each of a plurality components, and can include determining a group of potential interfering locations, based at least in part on the package height for the HG device, the PCB location for the HG device, the PCB locations, and respective component heights for at least a sub-plurality of the components among the plurality of components. This example disclosed method can include selecting, based at least in part on the determined group of potential interfering locations, a particular VC case configuration among the plurality of VC case configurations, and determining whether the particular VC case configuration remedies all of the potential interfering locations. In this example method, features can include, based at least on part on a positive determination that the particular VC case configuration remedies all of the potential interfering locations, electroforming the vapor chamber to form the vapor chamber case according to the particular VC case configuration, including rimless, seamless outer peripheral surfaces aligned and facing according to the particular case outer perimeter, and the other rimless, seamless lateral peripheral surfaces aligned and facing to form at least one clearance surface according to the particular one or more clearance perimeters

Another example disclosed method for vapor chamber thermal control can include storing a configuration data, including a PCB data, indicating a PCB dimension, a VC case configuration data that defines, at least in part, a VC case outer perimeter, a device data, identifying a package height of an HG device supportable on the PCB, a component data identifying a plurality of components supportable on the PCB, and respective heights of the components, and a layout configuration data defining, at least in part, a PCB device location for the HG device, and PCB locations for the components. The example method can further include determining a set of interfering locations, based at least in part on the PCB device location for the HG device, the PCB locations for the components, the package height of the HG device, and the VC case outer perimeter the device data and, upon the set of interfering components being a non-null set, determining a feasibility of updating the VC case configuration data, else proceeding to output the VC case configuration data for VC electroform fabrication, wherein determining the feasibility can include determining whether a clearance perimeter is feasible for interfering locations and, upon a negative result of determining the feasibility, exiting the method, else updating the VC case configuration data to include a clearance perimeter surrounding each interfering location.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIGS. 1A and 1B illustrate, respectively, a top view and a front view from the FIG. 1A projection plane 1-1, of an example printed circuit board (PCB) apparatus supporting a heat-generating (HG) device, overlaid with a rimmed case vapor chamber (VC) heat spreader, and in an example arrangement with other supported electronic components.

FIGS. 2A and 2B illustrate, respectively, a top view and a front view from the FIG. 2A projection plane 2-2, of an exemplary implementation of an adaptive clearance, electroformed (EF) rimless VC PCB system according to one or more aspects of the present application.

FIG. 3 illustrates one exemplary implementation of various outer perimeter features and inner clearance perimeter features of and provided through one or more adaptive clearance, rimless vapor chamber PCB systems and methods according to aspects of the present application.

FIGS. 4A and 4B illustrate, respectively, a top view and a front view from the FIG. 4A front cross-cut projection plane 4-4, of an exemplary implementation of an adaptive U-clearance, or open inner clearance, EF rimless VC PCB system according to one or more aspects of the present application.

FIG. 5 illustrates a top view of an exemplary implementation of an adaptive multi-clearance EF rimless VC PCB system according to one or more aspects of the present application.

FIGS. 6A and 6B illustrate, respectively, a top view and a front view from the FIG. 6B cross-cut projection plane 6-6, of an exemplary implementation of an adaptive multi-component clearance EF rimless VC PCB system according to one or more aspects of the present application.

FIGS. 7A and 7B illustrate, respectively, a top view and a font view from the FIG. 7A front cross-cut projection plane 7-7, of an exemplary implementation of one adaptive hybrid open clearance/closed clearance EF rimless VC PCB system according to one or more aspects of the present application.

FIG. 8 is a process flow chart representing logic flow of various exemplary operations within certain processes, in one or more implementations of adaptive clearance, EF rimless VC PCB systems and methods according to disclosed aspects.

FIG. 9 is a process flow chart representing logic flow of various exemplary operations within certain processes in one or more alternative implementations of adaptive clearance, EF rimless VC PCB systems and methods according to disclosed aspects.

FIG. 10 is a process flow chart representing logic flow of various exemplary operations within certain processes in one or more other alternative implementations, including adaptive assignment of open and closed inner clearance perimeters, in various adaptive clearance, EF rimless VC PCB systems and methods according to disclosed aspects.

FIG. 11 is a process flow chart representing logic flow 1100 of various exemplary operations within certain processes in one or more implementations of methods of automated PCB layout with adaptive clearance, EF rimless VC, according to various disclosed aspects.

FIG. 12 is a process flow chart representing logic flow of various exemplary operations within processes of EF fabrication of adaptive clearance, EF rimless VC devices, in one or more systems and methods according to disclosed aspects.

FIG. 13 is a process flow chart representing logic flow of various exemplary operations within processes in one or more other exemplary alternative implementations, including generation and storage of sets, groups, or pallets of adaptive clearance, EF rimless VC device configurations, and rule-based selections from among such sets, groups, or pallets, in various adaptive clearance, EF rimless VC PCB systems and methods according to disclosed aspects.

FIG. 14 is a functional block diagram of an example processor, configured to perform various exemplary processes and operations defined according to systems and methods according to one or more aspects of the present disclosure.

### DETAILED DESCRIPTION

In the following detailed description, numerous specific details are set forth by way of examples in order to provide a thorough understanding of the disclosed subject matter. It will be apparent to persons of ordinary skill, upon reading this description, that various aspects can be practiced without such details.

Aspects include a VC with readily variable clearances for PCB-specific and component-specific adaptability, of clearance parameters that can include a VC with adaptable clearance location, form and dimension, and population. This can allow positioning of PCB components, under the extending area of a VC, having a height greater than the space between the PCB support surface and the VC chamber bottom surface. Implementations can include, for example, adaptation of VC configuration to accommodate tall component proximal to an HG device, based on given PCB and PCB component configurations. Implementations can include rapid set up for fabrication, including ready customization of electroform mandrel, and subsequent electroforming of an application-specific optimized VC.

As will be understood by persons of skill upon reading this disclosure, benefits and advantages provided and enabled by disclosed subject matter and various implementations thereof can include, but are not limited to, a solution to the issues of inefficient area utilization, and related loss of available area for locating excess height components. Further benefits and advantages can include ready customization of the VC chamber, with significant degrees of freedom.

The phrase “heat-generating device,” as used in this disclosure, means a PCB supportable packaged device, or partially packaged device, having one or more thermal contact surfaces, including but not limited to a packaged single-chip IC microprocessor or other clocked logic device, a packaged multiple-chip microprocessor device, a packaged analog IC device, e.g., a power amplifier, either single-ship or multi-chip, that has been selected, specified, determined, or estimated as requiring a low thermal resistance heat path to carry at least a portion of a heat, either measured or estimated, from the PCB supportable packaged device.

The term “component,” as used herein, means any PCB supportable structure, electrical or non-electrical, active or passive including, but not limited to, packaged IC chip analog circuits, e.g., IC integrated amplifiers, packaged IC chip digital circuits, discrete resistors, discrete capacitors, discrete inductors, resistor arrays, and discrete transistors.

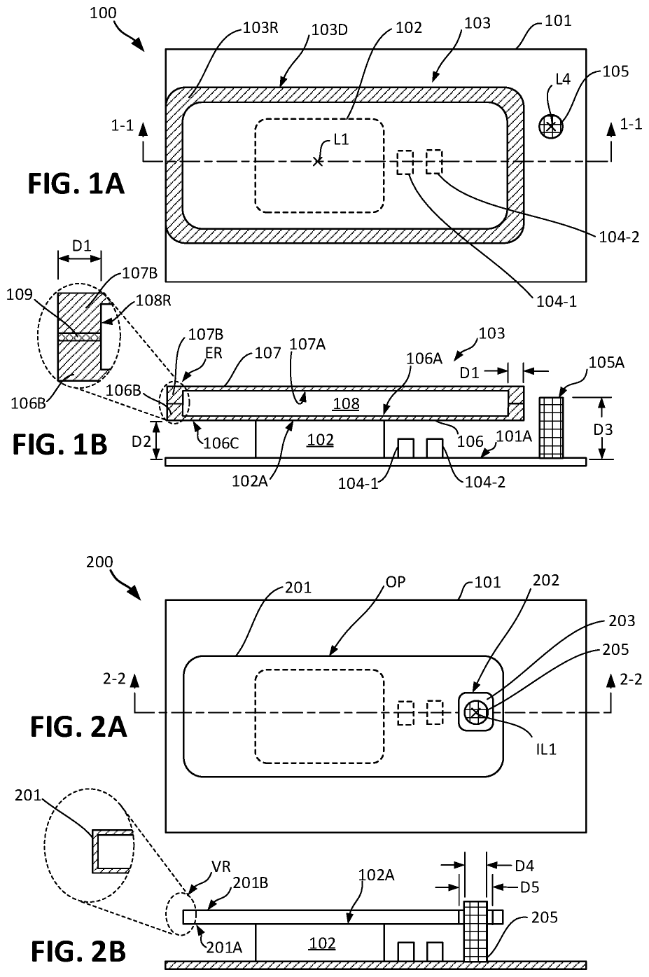

FIGS. 1A and 1B illustrate, respectively, a top view and a front view from the FIG. 1A projection plane 1-1, an example PCB apparatus 100 supporting that includes a PCB device 101 supporting, on a top support surface 101A, a HG device 102 overlaid by a rimmed, seamed, and bonded VC heat spreader 103. The surface 101A also supports an example arrangement of components 104-1 and 104-2 (collectively, “components 104”) and 105. The rimmed, seamed, and bonded VC heat spreader 103 is formed of a bottom shell 106 overlaid by a top shell 107. The bottom shell 106 has an etched recess 106A, surrounded by a remaining bottom peripheral rim 106B. The rim 106B has width D1. The top shell 107, in like manner, has an etched recess 107A—having the same diameter (visible but not separately labeled) as the bottom etched recess 106A—with a surrounding top peripheral rim 107B. The top rim 107A also has width D1 and matches the bottom peripheral rim 106B. To obtain the FIG. 1A-1B illustrated structure, the shell 107 and bottom shell 106 are positioned such their respective peripheral rims 106B and 107B are aligned and facing one another, whereupon pressure is applied to produce a diffusion bond between the facing surfaces of the top peripheral rim 107B and bottom peripheral rim 106B. The top and bottom recesses 106A and 107A then become respective bottom and top portions of a chamber 108.

Referring to the FIG. 1B enlarged region ER, the diffusion bond 109 can be seen. The overlaying top and bottom rims 106B and 107B form a substantially solid rim, of the width D1, extending outward from the peripheral edge 108R of the chamber 108. The extent of the rim 106A/107A, viewed from the FIG. 1A top projection plane, is marked by the cross-hatching 103R. The thick rim extending over 103R adds to the lateral diameter, and hence to the area occupied by the rimmed, seamed, and bonded VC heat spreader 103. The thick rim 103R also adds substantial weight to the rimmed, seamed, and bonded VC heat spreader 103, because it is essentially a solid rim of the thermal spreader metal, for example, copper, which has a density of 8.96 g/cm3.

The rimmed, seamed, and bonded VC heat spreader 103 has a bottom surface, provided by a bottom surface 106C of the bottom sheet metal pan 106, thermally coupled to the top surface 102A of the HG device 102. Opposite the bottom surface of 103 is a top surface provided by a top surface (visible but not separately labeled) of the top shell 107. That top surface is configured for thermal coupling to a cooling structure (omitted from FIGS. 1A-1B, to avoid obstruction of view), such as cooling fins, other head spreaders, an external housing or other enclosure, or can be insulated by air. Upon power-up, the HG device 102 generates heat that passes from the top surface 102A, through the bottom surface 106C of the rimmed, seamed, and bonded VC heat spreader 103. The heat starts a two-phase vaporization-condensation process that carries heat from its bottom surface 106C contact with the HG device top surface 102A, through to all outside surfaces of the VC heat spreader 103, including to its top surface for transfer to cooling fins or other heat exchanging structure.

Referring to FIG. 1B, a difference between component 105 and components 104 is that the height (visible but not separately labeled) that components 104 extend above the PCB top surface 101A is less than the distance D2 from 101A to the bottom surface of the rimmed, seamed, and bonded VC heat spreader 103. Component 105, on the other hand, has a height D3 that is greater than D2. D3 being greater than D2 can result in technical issues, including necessitating locating component 105 at a position outside the outer perimeter 103D of the rim. Features and aspects of the present disclosure can solve these technical issues, and can provide further benefits and advantages, as described in greater detail in later sections.

FIG. 2A illustrates a top view of an exemplary implementation of an adaptive clearance, electroformed (EF) rimless VC PCB system 200 (hereinafter referred to interchangeably as “adaptive clearance, EF rimless VC PCB system 200” and “system 200”) according to one or more aspects of the present application. FIG. 2B illustrates a front cross-cut view of the FIG. 2A adaptive clearance, EF rimless VC PCB system 200, viewed from the FIG. 2A front cross-cut projection plane 2-2. To avoid introducing new example structures not specific to disclosed aspects, and to provide for convenient comparisons to assist in understanding system 200 features and advantages, the system 200 will be described assuming the same PCB 101, the same HG device 102, the same components 104 and, except for its significant re-location provided by disclosed aspects, the same excess height component 105, re-numbered as “205.”

Referring to FIGS. 2A-2B, the adaptive clearance, EF rimless VC PCB system 200 includes an adaptive clearance, EF rimless VC 201, which can be mounted on the same upper surface 102A of the HG device 102 that supported the above-described example rimmed, diffusion bonded VC 105. The adaptive clearance, EF rimless VC 201 can have a bottom surface 201A. The FIG. 2A-2B example EF rimless VC 201 includes an outer perimeter “OP”, and an inner clearance perimeter 202. The inner clearance perimeter 202 defines a clearance 203 that is aligned with the location “IL1” of the re-positioned excess height component 205. The clearance 203 diameter D5 is greater than the diameter D4 of the excess height component 205. This placement and dimensioning allows the component 205 to be positioned within the outer perimeter OP. Instead of interfering with the EF rimless VC 201, the component 205 extends upward, unimpeded. Stated differently, instead of having to move the location “IL1” outside the outer perimeter OP of the EF rimless VC 201, the location IL1 is transformed from an interfering location to a usable location.

Referring to FIG. 2B, the enlarged region “VR” shows a partial cross-section of the outer, peripheral region of the EF rimless VC 201. As can be seen, there is no rim, i.e., no FIG. 1A-1B vertical walls 106A and 107A. Therefore, the EF rimless VC 201 can provide, in addition to ready accommodation of excess height components, other features and benefits, including but not limited to lower surface area, lower weight, thermal management.

It will be understood that the location, dimension, and shape or geometry of the FIG. 2A-2B example inner clearance perimeter 202 is only an example, and is not intended as a limit to practices according to this disclosure, or to indicate a preferred size or shape. Other shapes, sizes, and locations are illustrated and described in greater detail in later sections. Also, the number of inner clearance perimeters 202, i.e., one, illustrated in FIG. 2A-2B is not intended as a limitation or preference as to quantity. Other populations are illustrated and described in greater detail in later sections

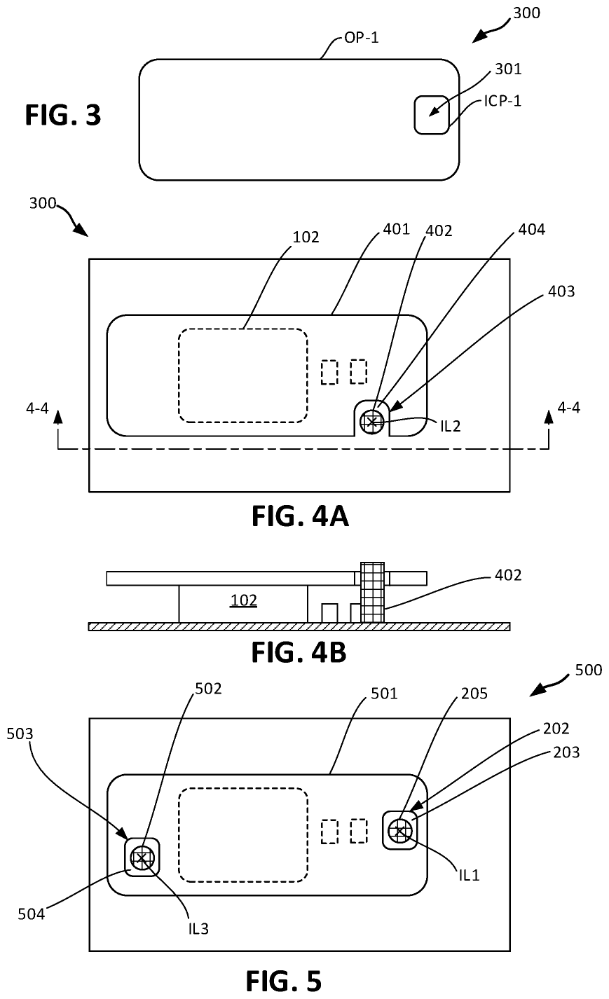

FIG. 3 illustrates one exemplary implementation of a VC case 300 with various outer perimeter features and clearance perimeter features provided through one or more adaptive clearance, rimless VC PCB systems and methods according to aspects of the present application. Referring to FIG. 3, the EF VC case 300 can enclose a chamber (not visible in FIG. 3) that extends substantially (except for wall thickness, not visible in FIG. 3) to the VC outer perimeter OP-1. The EF VC case 300 can include a clearance 301, with a clearance surface that is rimless, extending outward all the way to its clearance perimeter ICP-1.

FIGS. 4A and 4B illustrate, respectively, a top view and a front view from the FIG. 4A front cross-cut projection plane 4-4, of an exemplary implementation of an adaptive U-clearance, or open inner clearance perimeter, EF rimless VC PCB system 400 according to one or more aspects of the present application. The U-shaped or open clearance EF rimless VC 401 is adapted to accommodate the FIG. 2 system 200 component 205 (numbered “401” in FIGS. 4A-4B) being repositioned to “IL2.” There is no change in the position of the HG device 102. As illustrated, the result is that IL2 is too close to the outer perimeter OP to permit a closed perimeter clearance. The U-shaped clearance perimeter 403, defining clearance 404 solves that position issue.

FIG. 5 illustrates a top view of an exemplary implementation of an adaptive multi-clearance EF rimless VC PCB system 500 according to one or more aspects of the present application. The VC PCB system 500 includes an EF rimless VC case 501, illustrated as a modification of the FIG. 2A-2B system 200 EF rimless VC case 201, accommodating another excess height component, component 502, at position “IL3.” The accommodation is provided by second clearance perimeter 503, defining a second clearance 504.

The various aspects and exemplary implementations thereof described above use single-component clearance perimeters and clearances. For example, in FIGS. 2A-2B, clearance perimeter 202 and its defined clearance 203 surround one excess height component, 205. In like manner, in FIGS. 4A-4B, the U-shaped clearance perimeter 403 and its U-shaped clearance 404 accommodate one excess height component, 402

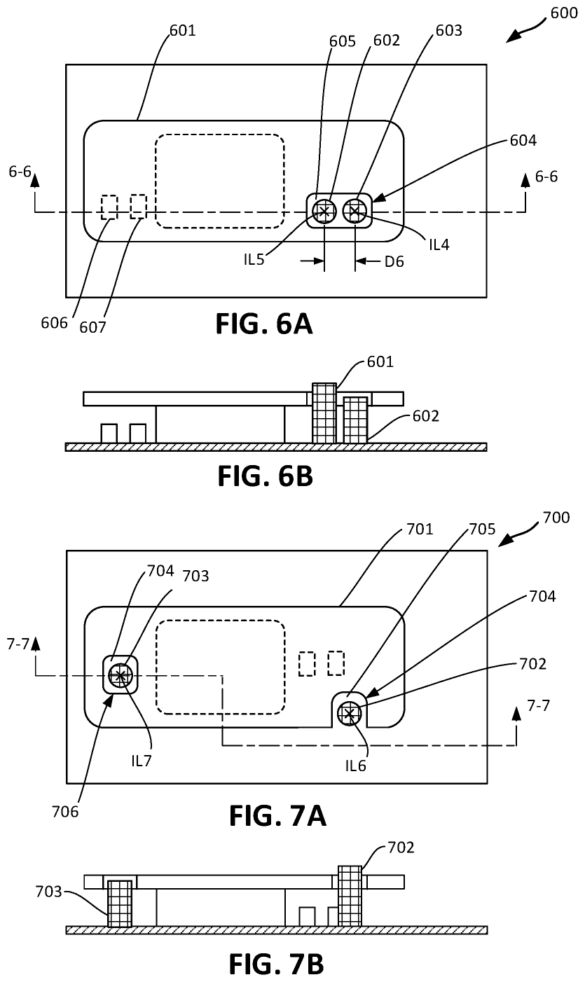

FIGS. 6A and 6B illustrate, respectively, a top view and a front view from the FIG. 6B cross-cut projection plane 6-6, of an exemplary implementation of an adaptive multi-component clearance EF rimless VC PCB system 600 according to one or more aspects of the present application. The system 600 EF rimless VC 601 is an adaptive accommodation of two excessive height components, a first component 602 and a second component 603 located, respectively, at first component position IL4 and second component position IL5. The first component position IL4 and second component position IL5 are spaced by distance D6. In a process described in greater detail in later sections, the first component position IL4 and second component position IL5 were determined, based at least in part on D6 and a spacing of IL4 and IL5 from the outer perimeter of the EF rimless VC 601, that a single clearance could encompass both first component position IL4 and second component position IL5. Accordingly, a multi-component clearance perimeter 604 was formed, defining the multi-component clearance 605. The system 600 also shows, for purposes of example, two lower-height components 606 and 607, within the outer perimeter but requiring no clearance.

FIGS. 7A and 7B illustrate, respectively, a top view and a front view from the FIG. 7A front cross-cut projection plane 7-7, of an exemplary implementation of one adaptive hybrid open clearance/closed clearance EF rimless VC PCB system 700 according to one or more aspects of the present application. The system 700 EF rimless VC 701 is an adaptive accommodation of another two excessive height components, a first component 702 and a second component 703 located, respectively, a first component position IL6 and second component position IL7. In a process described in greater detail in later sections, the first component position IL6 and second component position IL7 were determined, based at least in part on an outer perimeter of the EF rimless VC 701, and a distance between IL6 and IL7, as being a first interfering position and a second interfering position, incapable of being accommodated by a single clearance.

In an example implementation, operation within certain processes in one or more implementations of adaptive clearance, EF rimless VC PCB systems and methods according to disclosed aspects can include storing a VC configuration data that defines, at least in part, a configuration of a VC case. As described above, exemplary VC configuration data can include a VC case outer perimeter and can include a clearance perimeter, at least partially surrounding a clearance location within the VC case outer perimeter. Referring to FIG. 2A, examples are illustrated as the outer rim OP, the clearance 203 surrounding location ILL In a general aspect, operations can include electroforming a seamless case surrounding a chamber, based at least in part on the VC configuration data.

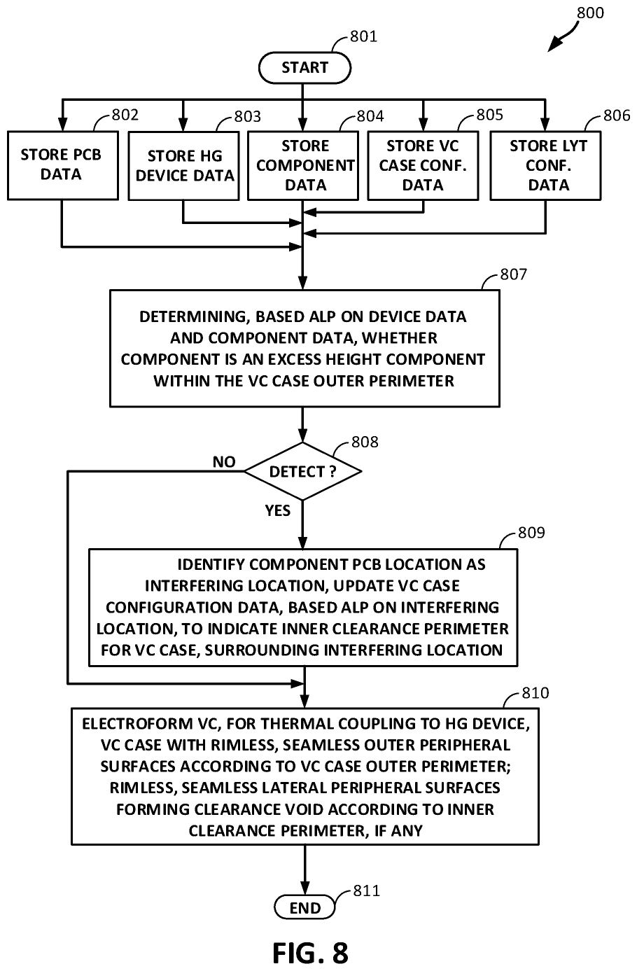

FIG. 8 is a process flow chart representing logic flow 800 of various exemplary operations within certain processes, in one or more implementations of adaptive clearance, EF rimless VC PCB systems and methods according to disclosed aspects.

Proceeding from an arbitrary start at 801, the flow can proceed to 802 where operations can be applied for storing a PCB data, indicating a PCB dimension. Operations can include, concurrently or sequentially with 802, a storing at 803 of a device data for a HG device supportable on the PCB, and a storing at 804 of a component data, including a component height data for a component supportable on the PCB. Other storing operations can include a storing at 805 of a VC case configuration data, including a VC case outer perimeter, such as the FIG. 3 VC case outer perimeter OP. Storing operations can include storing at 806 a layout data defining, at least in part, a PCB device location and a PCB component location, for the HG device and the component, respectively, on the PCB.

The flow 800 can proceed from the above-described storing operations 802, 803, 804, 805, and 806, to block 807, where operations can be applied that determine whether the PCB component location is a VC interfering location. The determination can be based, for example, at least in part on the PCB device location, the VC case outer perimeter, the package height data, the component height data, and the PCB component location. Upon determination at 807 of the PCB component location being an interfering location, the flow 800 can proceed from the decision block 808 “YES” outbranch to block 809 and apply operations for updating the VC case configuration data. The updating can be based at least in part on the interfering location determined at 807, to include an inner clearance perimeter for the VC case, surrounding the VC interfering location. The flow 800 can proceed from 809 to block 810 where operations can be applied for electroforming a vapor chamber, for thermal coupling to the HG device. The electroformed vapor chamber can include a vapor chamber case with rimless, seamless outer peripheral surfaces aligned and facing according to the VC case outer perimeter, and other rimless, seamless lateral peripheral surfaces aligned and facing to form a clearance according to the clearance perimeter, if any.

Referring to FIG. 8, if operations at 807 find no interfering locations, the flow 800 can be routed, from the “NO” outbranch from decision block 808, directly to block 810 for forming the vapor chamber, without clearances.

The above-described example includes only one PCB component and component location. A layout configuration data can further define a PCB second component location, for a second component on the PCB, and second component height data, indicating a height of the second component. An aspect can include determining whether the second PCB component location is a VC second interfering location. The determination can be based for, example, at least in part, on the PCB device location, the VC case outer perimeter, the package height data, the second component height data and PCB second component location. In addition, upon determining the PCB component location being a VC second interfering location, operations can include updating the VC case configuration data such that the electroforming forms the clearance surface aligned and facing to surround and clear both the first and the second VC interfering locations.

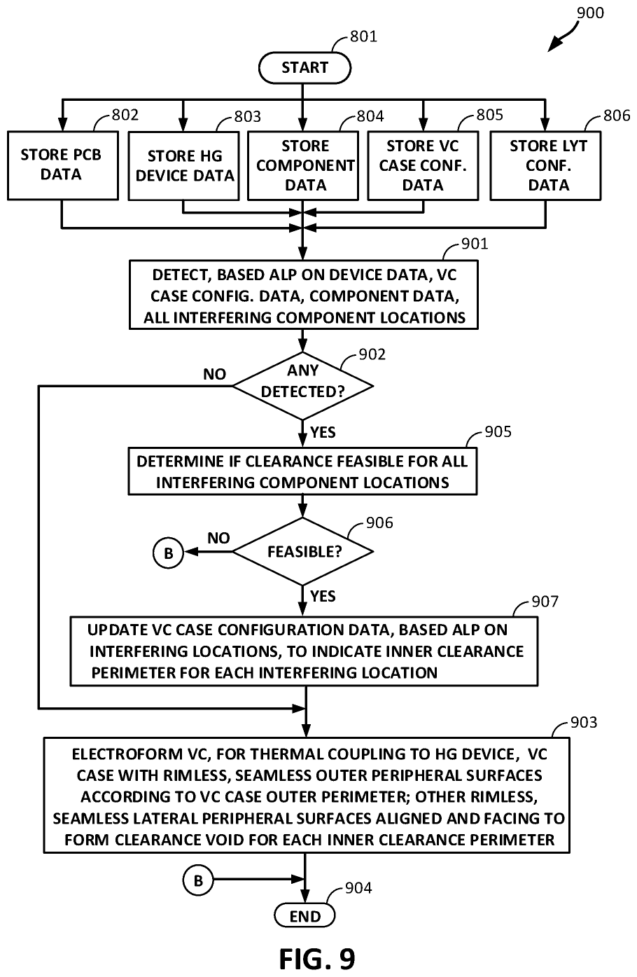

FIG. 9 is a process flow chart representing logic flow 900 of various exemplary operations within certain processes, in one or more implementations of adaptive clearance, EF rimless VC PCB systems and methods according to disclosed aspects. The illustrated implementation uses certain blocks in accordance with the FIG. 8 flow 800. For brevity, such blocks are labeled and numbered the same as in FIG. 8, and their description is not repeated. Referring to FIG. 9, proceeding from the arbitrary start at 801, the flow 900 can store, at 802, 803, 804, 805, and 806, the above-described configuration data, including PCB data, indicating a PCB dimension, VC case configuration data that defines, at least in part, a VC case outer perimeter, device data, identifying a package height of a HG device supportable on the PCB, component data identifying a plurality of components supportable on the PCB, and respective heights of the components, and a layout configuration data defining, at least in part, a PCB device location for the HG device, and PCB locations for the components.

Upon the storing operations at 802, 803, 804, 805, and 806, the flow 900 can proceed to 901, and apply operations of detecting all interfering component locations, i.e., all component locations within the outer perimeter of the EF rimless VC PCB where the associated component height exceeds the HG device height. Components at such locations will interfere with the underside of the EF rimless VC PCB such as the FIG. 2A-2B VC 201. Upon operations at 901 finding no interfering locations, i.e., the set of interfering components being a null set, the flow 900 can proceed, from the “NO” out branch of decision block 902 to block 903, where operations can electroform the EF rimless VC, configured for thermal coupling to the HG device, with no clearance, using, for example, the VC configuration data outer perimeter (e.g., the FIG. 3 OP-1). The flow 900 can then proceed to end state at 904.

Upon operations at 901 finding interfering components, the flow 900 can proceed from the “YES” out branch of decision block 902 to block 905, where operations can be applied to determine the feasibility of the adapting the EF VC to accommodate all of the interfering components. The determination can be made, for example, based at least in part on the number of interfering components. Upon a negative result of the block 905 determination, the flow 900 can proceed, from the “NO” outbranch of decision block 906, to the end state 904. Upon a positive result of the block 905 determination, the flow 900 can proceed, from the “YES” outbranch of decision block 906, to block 907, where operations can be applied that update the VC case configuration data to include an inner clearance perimeter surrounding each interfering location. The flow 900 can proceed from block 907 to block 903, where operations can electroform a vapor chamber, configured for thermal coupling to the HG device, including rimless, seamless lateral peripheral surfaces aligned and facing to form a clearance according to each inner clearance perimeter.

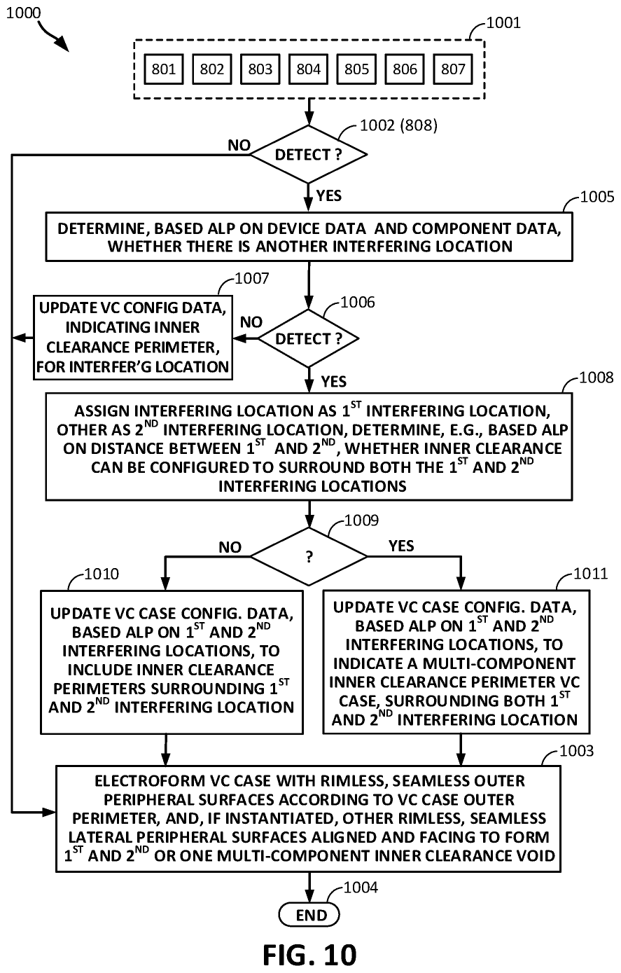

FIG. 10 is a process flow chart representing logic flow 1000 of various exemplary operations within certain processes in one or more other alternative implementations. An exemplary instance of the flow 1000 can start at 1001, where operations can be performed for storing, for example, in a memory of a general purpose programmable processor, a configuration data such as described in above reference to the FIG. 8 flow blocks 801, 802, 803, 804, 805, and 806. The exemplary data includes a PCB data, indicating a PCB dimension, VC case configuration data that defines, at least in part, a VC case outer perimeter, device data, identifying a package height of an HG device supportable on the PCB, component data identifying a plurality of components supportable on the PCB, and respective heights of the components, and a layout configuration data defining, at least in part, a PCB device location for the HG device, and PCB locations for the components. For purposes of description, it will be assumed that the respective component heights of at least a first component and a second component among the plurality of components exceed the package height of the HG device.

Referring to FIG. 10, the flow 1000 can proceed from 1001 to block 1002 where operations can be applied to determine whether the PCB position any among the first component and second component is an interfering position. The specific operations can be implemented in various configurations. For example, a processing operation can translate, using the position of the HG device, the outer perimeter of the EF VC case to a contour of positions on the PCB. The processing operation can also set, based at least in part on the height of the HG device package, a “do-not-exceed” height for components that are within outer perimeter, i.e., located under, the EF VC case. The processing operation can then select all component positions within the outer perimeter, for example, as potential interfering positions, and then for each of the potential interfering positions, compare the component height to the do-not-exceed height. If there are no potential interfering positions, or if none of the potential interfering positions has a component height above the do-not-exceed value, the determination at 1002 is NO. The flow 1000 then proceeds to block 1003, where operations can be applied to electroform the EF VC case, without clearances, using, for example, the original VC case configuration data stored at 1001. The flow 1000 can then proceed to block 1004 and end.

If the determination at block 1002 is YES, i.e., one of the potential interfering positions has a component height above the do-not-exceed, the flow 1000 can proceed to block 1005. At block 1005 operations can be applied that determine if there are any other interfering positions. Implementation of such operations at 1005 can be according to implementation of the operations at block 1002. For example, if operations at block 1002 listed all component positions within the outer perimeter as potential interfering positions and the flow 1000 had proceeded from 1002 to 1005 based on determining one of the potential interfering positions being an interfering position, operations at block 1005 may include removing that potential interfering position from the list and then making a two-step determination. The first step can be determining if there are any remaining potential interfering positions. If the answer is no, the flow 1000 can proceed from NO at decision block 1006 and then to block 1007 and apply operations that update the VC configuration data to indicate an inner clearance perimeter surrounding the interfering position. Depending on the specific location of the interfering position the clearance perimeter can be a closed perimeter, such as the FIG. 2A exemplar 202, or an open or U-shaped perimeter, such as the FIG. 4A exemplar 403. The flow 1000 can then proceed from block 1007 to block 1003, where operations can be applied that electroform the EF VC case with a clearance, using, for example, the original VC case configuration data stored at 1001 modified to include the inner clearance perimeter. The flow 1000 can then proceed from block 1003 to block 1004 and end.

Referring to FIG. 10, and the above-described determination of YES at block 1002 and corresponding procession of the flow 1000 to block 1005. If there other potential interfering locations remain after resolving the interfering location at block 1002, i.e., operations at 1005 can include determining if any is an interfering location. If the answer is no, the flow 1000 can proceed as described above, from NO at decision block 1006, to block 1007 to update the VC configuration data to indicate an inner clearance perimeter surrounding the interfering location identified at block 1002, and then to block 1003 to electroform the VC case accordingly. If operations at block 1005 determine that another of the potential interfering locations is an interfering location, the flow 1000 can proceed from a YES at decision block 1006 to 1008, where operations can be applied that can assign the interfering location as a first interfering location and the other interfering location as a second interfering location. In an aspect, operations at block 1008 can be configured to determine whether one inner clearance perimeter can encompass both the first and second interfering locations, or whether separate first and second inner clearance perimeters should be formed. Such operations can include, for example, computing a distance between the first and second interfering locations. Such operations can be further based upon the distance and, for example, respective diameters of the excess height components at the two locations, and respective distances between the outer perimeter of the EF VC case and one or both of the first and second interfering locations.

Referring to FIG. 10, and assuming an instance of the flow 1000 where operations at 1008 determine that a single inner clearance perimeter, surrounding both the first and second interfering locations, cannot be formed, the flow 1000 can proceed from the NO outbranch of decision block 1009 to block 1010, where operations can be applied that update the VC configuration data to include a first inner clearance perimeter and a second inner clearance perimeter. Depending on the respective locations of the first and second interfering locations, e.g., relative to the outer perimeter of the EF VC case, results of such operations at 1010 can, for example, be according to the FIG. 5 clearance perimeters 203 and 503, or according to the FIG. 7A-7B inner clearance perimeters 704 and 706. The flow 1000 can then proceed from block 1010 to block 1003, where operations can be applied that electroform the EF VC case with a first and a second clearance, using, for example, the original VC case configuration data stored at 1001 modified to include a first and a second clearance perimeter. The flow 1000 can then proceed from block 1003 to the ends state at block 1004.

Referring to FIG. 10, and assuming an instance of the flow 1000 where operations at block 1008 determine that a single clearance perimeters, surrounding both the first and second interfering locations can be formed, the flow 1000 can proceed from the YES outbranch of decision block 1009 to block 1011, where operations can be applied that update the VC configuration data to include a multi-component clearance perimeter that encompasses both the first and the second interfering locations. Results of such operations at 1011 can be according, for example to the FIG. 6A-6B multi-component clearance perimeter 604. The flow 1000 can then proceed from block 1011 to block 1003, where operations can be applied that electroform the EF VC case with a multi-component clearance, using, for example, the original VC case configuration data stored at 1001 modified to include the multi-component inner clearance perimeter. The flow 1000 can then proceed from block 1003 to block 1004 and end.

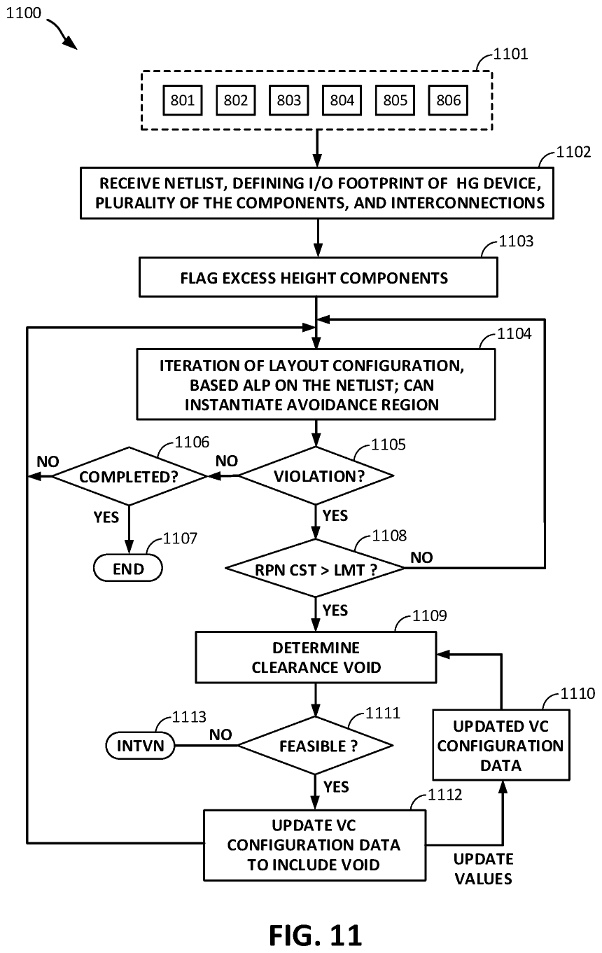

FIG. 11 is a process flow chart representing logic flow 1100 of various exemplary operations within certain processes in one or more exemplary implementations of methods of automated PCB layout with adaptive clearance, EF rimless VC, according to various disclosed aspects. An exemplary instance of the flow 1100 can start at block 1101, where operations can store a PCB dimension data, VC case configuration data that defines, at least in part, a VC case outer perimeter, device data, identifying an I/O footprint and a package height of an HG device supportable on the PCB, component data identifying an I/O footprint of a plurality of components supportable on the PCB, and respective heights of the components. The flow can proceed from block 1101 to block 1102, where operations can include storing a netlist, defining I/O interconnections among and between the HG device and the components. The flow 1100 can proceed from block 1102 to block 1103, where operations can flag excess height components, meaning components having a height greater than the HG device. It will be understood that “flag” can mean any information or correspondence and does not necessarily require an explicit indicator.

The flow 1100 can proceed from block 1103 to block 1104, where operations can apply an iteration of generating a layout. If the iteration places the HG device at a location then, based on that location and an outer perimeter of the VC case, an avoidance zone is instantiated. Prior to placing the HG device, there may not be an avoidance region. Either sequential to, or included in the iteration at block 1104, operations represented by decision block 1105 can detect whether the iteration causes a violation of the avoidance region. In other words, if it positioned an excess height component in the avoidance region. Or if the avoidance region was instantiated to overlay an already-created position for an excess height component. Absent detecting a violation, the flow 1100 can proceed from block 1105 to termination condition block 1106 that, upon completion of the layout process, routes the flow 1100 from the block's “YES” out branch to the end state 1107. Assuming the layout process is not complete, the block 1106 “NO” out branch routes the flow 1100 back to block 1104 for another iteration.

Upon detecting a violation at block 1105, the block's “YES” outbranch can route the flow 1100 to block 1108 where operations can be applied that can compare a cost, or estimated cost of repositioning the excess height component that caused the violation to a position outside the avoidance region. The “cost” can be defined according to various metrics, or combinations of metrics including, for example, man-hours of rework time, propagation penalty, and PCB space utilization. The decision at block 1108 can be defined, for example, as a single metric threshold, or a weighted multiple metric threshold. If the cost is determined not excessive, the block's “NO” outbranch can route the flow 1100 back to block 1104 for an iteration that can move the subject excess height component to a location outside the avoidance region. If block 1108 determines the cost as excessive or otherwise not acceptable, the 1108 “YES” outbranch can route the flow 1100 to block 1109 where operations can define a clearance perimeter for the EF VC that will accommodate the subject excess height component. As will be described in greater detail in reference to subsequent blocks in the FIG. 11 flow 1100, each generation of another clearance perimeter will correspondingly update the VC configuration data.

FIG. 11 block 1110 stores the most recent updated VC configuration data, and that can be pushed to 1109 for the next iteration of the loop, as represented by the information flow arrow pointing from block 1110 to block 1109. The updating of the VC configuration data in block 1110 to reflect each clearance perimeter can provide for sequential generation of multiple clearances that are mutually compatible and consistent with the desired thermal performance of the adapted VC device. Related to this, either sequential to or included in the operations at block 1109, operations such as represented by block 1111 can determine, or estimate, whether the necessary clearance to accommodate the component causing the most recent violation at block 1105, is feasible. One feasibility metric can be, for example, a “remaining VC area,” based at least in part on a percentage total remaining VC area, accounting for all clearances.

In instances where block 1111 determines it is not feasible to form a clearance to accommodate the most recently detected interfering excess height component, the “NO” outbranch from 1111 can route the flow 1100 to block 1113 where, for example, an automatic intervention or a human intervention, or both, can be applied (labeled “INTVN” in FIG. 11).

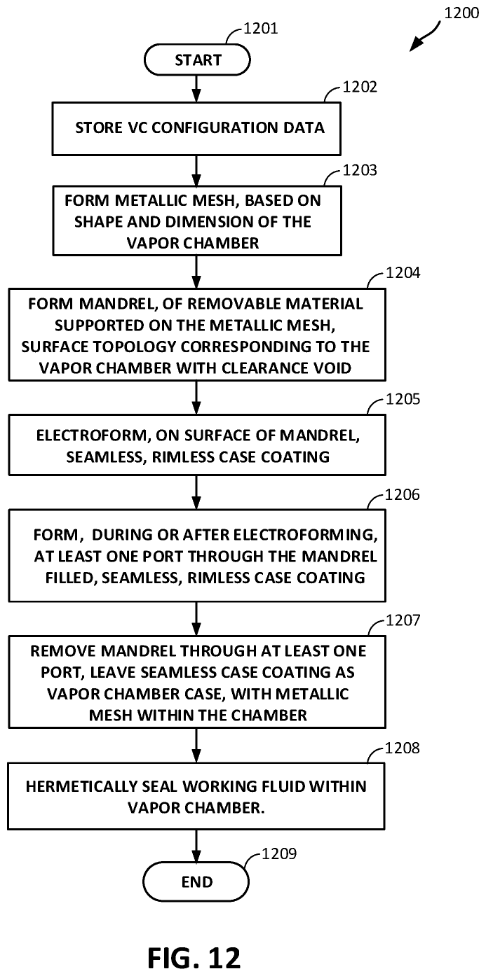

FIG. 12 is a process flow chart representing logic flow 1200 of various exemplary operations within certain processes of EF fabrication of adaptive clearance, EF rimless VC devices, in one or more implementations of adaptive clearance, EF rimless VC PCB systems and methods according to disclosed aspects. In an aspect, the actual fabrication of an exemplary adaptive clearance, EF rimless VC in accordance with the present disclosure, can be an adaptation of the fabrication process disclosed in U.S. Patent Application Publication No. 2018/0164042 (published on Jun. 14, 2018), which is herein incorporated by reference in its entirety.

An exemplary instance of the process flow 1200 can proceed from arbitrary start at 1201 to block 1202, where operations can be applied that form a mesh, the mesh being based at least in part on a shape and dimension of an EF vapor chamber, as described above in reference to any of FIGS. 2A-2B, 3, 4A-4B, 5, 6A-6B, and 7A-7B, or any variation thereof, or any combination or sub-combination thereof. The mesh may be composed of one or more materials, for example, any one or more from among a metal, a polymer, or a natural fiber.

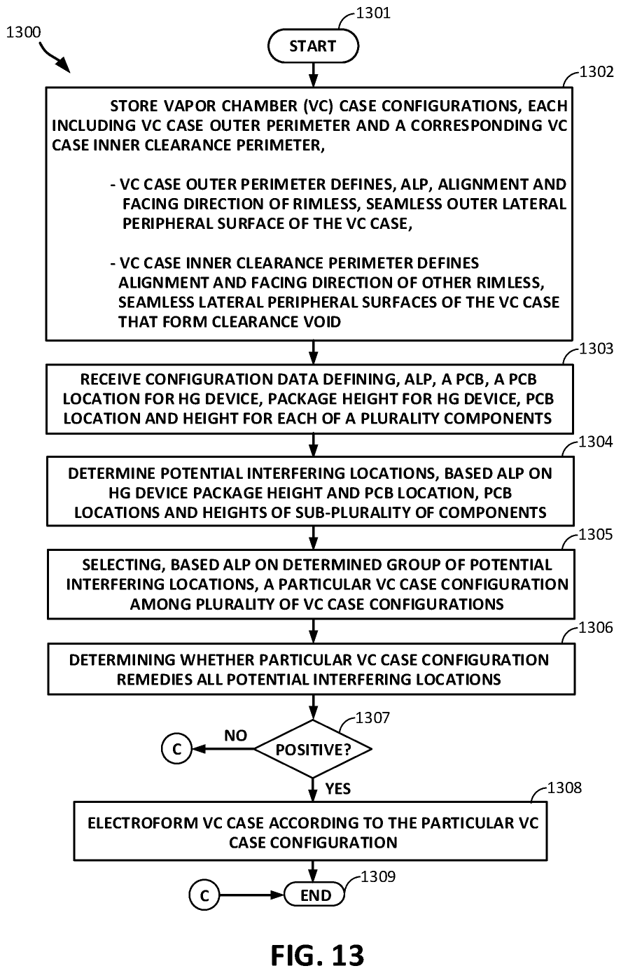

EF VC configuration data defining such shapes and dimensions, as well as combinations and variations of same, can be generated by methods, for example, in accordance with any of those described above in reference to any of FIGS. 8, 9, 10, 11, or further described in greater detail in reference to FIG. 13, or any combination or sub-combination thereof. Such EF VC configuration data can be stored, for example, in a memory of a general purpose programmable computer associated with, or configured for controlling, or monitoring, or both, an electroform fabrication process at an electroform fabrication facility. The process flow 1200 can proceed from 1202 to 1203, where operations can be applied that can form a mandrel, for example, on the mesh, of a removable material, e.g., chemically dissolvable. The mandrel can have a surface topology corresponding to the EF vapor chamber, as defined by the EF VC configuration data. The process flow 1200 can proceed from 1203 to 1204, where operations can be applied that electroform, on the surface of the mandrel, a seamless, rimless metal case coating or wall. The metal case coating can be, for example, copper (Cu). The thickness of the coating, or wall, can be application-specific. The process flow can include forming, as represented by block 1205, either during or after the electroforming operation, at least one port through which the mandrel material can be removed. The process flow 1200 can proceed from 1205 (or the combination of 1204 and 1205) to 1206, where operations, e.g., chemical solvent operations, can be applied to remove the mandrel.

The process flow 1200 can proceed from 1206 to 1207, where operations can inject a working fluid, for example, water, into the chamber. The injection can be performed, for example, using the port (or one of the ports) used for removing the mandrel. The process flow 1200 can then proceed to 1208, where operations can hermetically seal the vapor chamber, and end at 1209.

FIG. 13 is a process flow chart representing logic flow 1300 of various exemplary operations within certain processes in one or more other exemplary alternative implementations. Processes according to the flow 1300 can include generation and storage of sets, groups, or pallets of adaptive clearance, EF rimless VC device configurations, and can include certain rule-based selections from among such sets, groups, or pallets, in various adaptive clearance, EF rimless VC PCB systems and methods according to disclosed aspects.

FIG. 13 is a process flow chart representing logic flow 1300 of various exemplary operations within certain processes in one or more other exemplary alternative implementations. Processes according to the flow 1300 can include generation and storage of sets, groups, or pallets of adaptive clearance, EF rimless VC device configurations, and can include certain rule-based selections from among such sets, groups, or pallets, in various adaptive clearance, EF rimless VC PCB systems and methods according to disclosed aspects.

An exemplary instance of the process flow 1300 can proceed from arbitrary start at 1301 to block 1302, where operations can be applied that store, for example in a memory of a general purpose programmable computer, a plurality VC case configurations. Each VC case configuration can include a corresponding VC case outer perimeter and a corresponding VC case inner clearance perimeter. In an aspect, the VC case outer perimeter can define, at least in part, an alignment and a facing direction of a rimless, seamless outer lateral peripheral surface of the VC case. The VC case clearance perimeter can define an alignment and facing direction of other rimless, seamless lateral peripheral surfaces of the VC case that form a clearance, for example the FIG. 3 ICP-1, or any one or more the clearance perimeters illustrated in FIGS. 2A-2B, 4A-4B, 5, 6A-6B, or 7A-7B. The flow 1300 can proceed from block 1302 to block 1303, where operations can be applied that can include receiving a configuration data defining, at least in part, a PCB, a PCB location for an HG device, a package height for the HG device, and a PCB location and a component height for each of a plurality components.

The flow 1300 can proceed from block 1303 to block 1304, where operations can be applied that can determine a group of potential interfering locations, based at least in part on the package height for the HG device, the PCB location for the HG device, the PCB locations, and respective component heights for at least a sub-plurality of the components among the plurality of components. The flow 1300 can proceed from block 1304 to block 1305, where operations can be applied that can select, based at least in part on the determined group of potential interfering locations, a particular VC case configuration among the plurality of VC case configurations. The flow 1300 can then proceed from block 1305 to block 1306, where operations can be applied that can determine whether the particular VC case configuration remedies all of the potential interfering locations. If the result of the block 1306 processing is no, the flow 1300 can be routed, for example from the “NO” outbranch from decision block 1307, to the end state 1309. Referring again to FIG. 13, blocks 1306 and 1307, if processing at 1306 determines the particular VC case configuration remedies all of the potential interfering locations, the 1300 can be routed, for example from the “YES” outbranch from decision block 1307, to block 1308, where operations can be applied that electroform the vapor chamber case according to the particular VC case configuration.

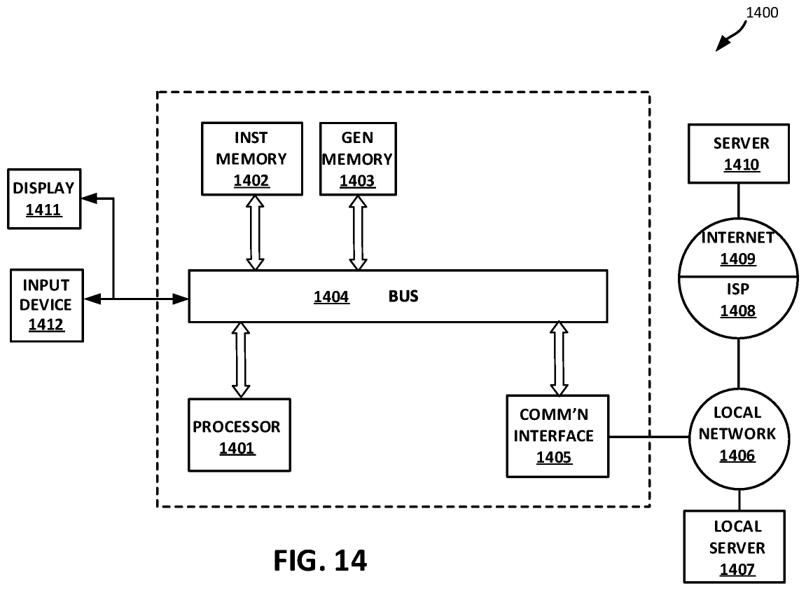

FIG. 14 is a functional block diagram of a processor 1400, configured to perform operations and processes in systems and methods according to the present disclosure. It will be understood that functional blocks illustrated in FIG. 14 are logical blocks, and do not necessarily correspond to particular hardware.

Referring to FIG. 14, the processor 1400 can include a data processor 1401, a general purpose memory 1402, and an instruction memory 1403 coupled by a bus 1404. The instruction memory 1403 can include a tangible medium retrievably storing computer-readable instructions that when executed by the data processor 1401 cause the processor to perform operations in accordance with the flow diagrams of FIGS. 8, 9, 10, 11, 12, and 13. The processor 1400 can include a communication interface 1405, to a local network 1406, which can connect to a local server 1407. The local network 1406 can also connect, through an Internet Service Provider (ISP) Internet 1408, and to the Internet 1409. The local network 1406 can access a remote server 1410 through the Internet. The processor 1400 can include a display 1411 and an input device 1412, e.g., a touchscreen, mouse, keyboard, or voice interface.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows, and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing stated or illustrated herein is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein.

Relational terms such as first and second and the like may be used solely to distinguish one entity or action from another without necessarily requiring or implying any such first, second relationship or order between such entities or actions. The terms “comprises,” “comprising,” and any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “a” or “an” does not, without further constraints, preclude the existence of additional identical elements in the process, method, article, or apparatus that comprises the element.

The Abstract of the Disclosure is provided to allow the reader to quickly identify the nature of the technical disclosure. It is submitted with the understanding that it will not be used to interpret or limit the scope or meaning of the claims. In addition, in the foregoing Detailed Description, it can be seen that various features are grouped together in various examples for the purpose of streamlining the disclosure. This method of disclosure is not to be interpreted as reflecting an intention that any claim requires more features than the claim expressly recites. Rather, as the following claims reflect, inventive subject matter lies in less than all features of a single disclosed example. Therefore, the following claims are hereby incorporated into the Detailed Description, with each claim standing on its own as a separately claimed subject matter.

What is claimed is:

1. A method, comprising:
storing a vapor chamber (VC) configuration data that defines, at least in part, a surface topology of the VS case, including
a VC case outer perimeter, in a plane, and
a clearance perimeter, at least partially surrounding a clearance location within the VC case outer perimeter; and
electroforming a seamless case surrounding a chamber, the seamless case having an external surface that includes:
a top surface and a bottom surface, spaced apart by a height, aligned with the VC case outer perimeter,
a rimless outer peripheral surface extending around the case center, along the case outer perimeter, and
a rimless clearance surface, extending along the clearance perimeter from the top surface to the bottom surface, at least partially surrounding the clearance location.

2. The method of claim 1, wherein:
the clearance location is a first clearance location,
the clearance perimeter is a first clearance perimeter
the VC configuration data further defines, at least in part, a second clearance perimeter, at least partially surrounding a second clearance location within the VC case outer perimeter, and
electroforming the seamless case includes forming the external surface to also include a second rimless clearance surface, extending along the second clearance perimeter from the top surface to the bottom surface, at least partially surrounding the second clearance location.

3. The method of claim 1, wherein:
the clearance perimeter is a closed perimeter, within the VC case outer perimeter, and
electroforming the vapor chamber further forms the rimless clearance surface as a closed perimeter rimless clearance surface.

4. The method of claim 1, wherein:
the clearance perimeter is a U-shaped form that extends inward from the VC case outer perimeter, and
electroforming the vapor chamber further forms the rimless clearance surface as a U-shaped recessed rimless clearance surface.

5. The method of claim 1, further comprising:
storing a printed circuit board (PCB) data, indicating a PCB dimension,
storing a device data, identifying a package height of a heat-generating (HG) device supportable on the PCB,
storing a component data identifying a component supportable on the PCB, and a height of the component,
storing a layout configuration data defining, at least in part, a PCB device location for the HG device, and a PCB location for the component;
determining, based at least in part on the PCB device location for the HG device, the PCB location for the component, the package height of the HG device, the height of the component, and the VC case outer perimeter, whether the component location is an interfering location;
upon the component location being an interfering location, storing the VC configuration data includes updating the VC case configuration data to include the clearance location and the clearance perimeter, the clearance location being the interference location, and the clearance perimeter being configured to at least partially surround the clearance location.

6. The method of claim 5, wherein:
the component data further includes a component diameter, and
determining whether the component location is an interfering location is further based, at least in part, on the component diameter.

7. The method of claim 6, wherein:
updating the VC case configuration data to include the clearance perimeter further includes configuring the clearance perimeter to have a clearance diameter, the clearance diameter being based, at least in part, on the component diameter.

8. The method of claim 5, wherein:
the component is a first component,
the component data also identifies a height of a second component supportable on the PCB,
the layout configuration data further defines, at least in part, a PCB location for the second component, and
wherein the method further includes
determining, based at least in part on the PCB device location for the HG device, the PCB location for the second component, the package height of the HG device, the height of the second component, and the VC case outer perimeter, whether the second component location is another interfering location;
upon the second component location being another interfering location,
setting the clearance location as a first clearance location, and the clearance perimeter as a first clearance perimeter,
including in storing the VC configuration data a further updating of the VC case configuration data to also include a second clearance location and a second clearance perimeter, the second clearance location being the another interference location, and the second clearance perimeter being configured to at least partially surround the second clearance location, and
based at least in part on the second component location being another interfering location, including in electroforming the vapor chamber an electroforming of a second rimless clearance surface, extending along the second clearance perimeter from the top surface to the bottom surface, at least partially surrounding the second clearance location.

9. The method of claim 8, wherein:
the component data further includes a first component diameter and a second component diameter,
determining whether the first component location is an interfering location is further based, at least in part, on the first component diameter, and
determining whether the second component location is another interfering location is further based, at least in part, on the second component diameter.

10. The method of claim 9, wherein updating the VC case configuration data to include the first clearance perimeter and the second clearance perimeter further includes:
configuring the first clearance perimeter to have a first clearance diameter, the first clearance diameter being based, at least in part, on the first component diameter, and
configuring the second clearance perimeter to have a second clearance diameter, the second clearance diameter being based, at least in part, on the second component diameter.

11. The method of claim 10, wherein:
the VC case configuration data further defines:
the first clearance perimeter as a closed perimeter, within the VC case outer perimeter, and
the second clearance perimeter with a U-shaped form that extends inward from the outer perimeter,
electroforming the first rimless clearance surface includes electroforming the first rimless clearance surface as a closed perimeter first rimless clearance surface, surrounding the first clearance location, and
electroforming the second rimless clearance surface includes electroforming the second rimless clearance surface as a U-shaped recessed second rimless clearance surface.

12. The method of claim 10, wherein:
the VC case configuration data further defines:
the first clearance perimeter as a first closed perimeter, within the VC case outer perimeter, and
the second clearance perimeter as a second closed perimeter, within the VC case outer perimeter,
electroforming the first rimless clearance surface includes electroforming the first rimless clearance surface as a closed perimeter first rimless clearance surface, surrounding the first clearance location, and
electroforming the second rimless clearance surface includes electroforming the second rimless clearance surface as a closed perimeter second rimless clearance surface, surrounding the second clearance location.

13. The method of claim 8, wherein:
based at least in part on the second component location being another interfering location, the method further comprises:
computing, based at least in part on a distance between the first interfering location and the second interfering location, whether the first rimless clearance surface can be configured to surround both the first interfering location and the second interfering location, and
upon a positive result of the computing,
updating the VC case configuration data, based at least in part on the first interfering location and the second interfering location, to indicate the first clearance perimeter being a multi-component clearance perimeter for the VC case, the multi-component clearance perimeter surrounding both the first interfering location and the second interfering location, and
configuring the electroforming the vapor chamber to form a multi-component rimless clearance surface, extending along the multi-component clearance perimeter from the top surface to the bottom surface, at least partially surrounding the first interfering location and the second interfering location.

14. The method of claim 1, wherein the component data identifies the component supportable on the PCB as a component among a plurality of components supportable on the PCB, and indicates respective heights of the components, and
wherein the method further comprises:
receiving a netlist that defines an input/output (I/O) footprint of the HG device, an I/O footprint of the plurality of the components, and interconnections among and between the I/O footprint of the HG device and the respective I/O footprints of the plurality of components; and
generating the layout configuration, based at least in part on the netlist, the height of the HG device package, and the respective heights of the components, the layout configuration defining PCB locations for the plurality of the components,
wherein:
at least one of the components is an excess height component,
generating the layout configuration includes
identifying, for the excess height component, a candidate interfering position,
determining a feasibility of the candidate interfering location,
based at least in part on a computing of a vapor chamber performance change, the computing including defining a candidate clearance at the candidate interfering location, and computing a prediction of an effect on performance of the vapor chamber that would likely result.

15. The method of claim 1, wherein electroforming includes:
forming a metallic mesh, having a shape and dimension that is based, at least in part, on a shape and dimension of the vapor chamber;
forming a mandrel, on the metallic mesh, the mandrel having a surface topology that corresponds to the vapor chamber, and to the clearance, the mandrel including a melt material supported at least in part by the metallic mesh;
electroforming, on the surface of the mandrel, a seamless, rimless case coating;
forming, during the electroforming or after the electroforming, at least one port through the mandrel filled seamless, rimless case coating;
removing the mandrel melt material, at least in part through the at least one port, leaving the seamless case coating as the vapor chamber case, with the metallic mesh within the vapor chamber;
inserting a working fluid into the vapor chamber, through the at least one port, or through another port, or through both; and
hermetically sealing the working fluid within the vapor chamber.

16. A method, comprising:
storing a plurality of vapor chamber (VC) case configurations, each VC case configuration including a corresponding case outer perimeter and case clearance perimeter, wherein
the case outer perimeter defines, at least in part, an alignment and a facing direction of a rimless, seamless outer lateral peripheral surface of the VC case,
the clearance perimeter defines an alignment and facing direction of other rimless, seamless lateral peripheral surfaces of the VC case that form a clearance surface;
receiving a configuration data defining, at least in part, a printed circuit board (PCB), a PCB location for a heat generating (HG) device, a package height for the HG device, and a PCB location and a component height for each of a plurality components;
determining a group of potential interfering locations, based at least in part on the package height for the HG device, the PCB location for the HG device, the PCB locations, and respective component heights for at least a sub-plurality of the components among the plurality of components;
selecting, based at least in part on the determined group of potential interfering locations, a particular VC case configuration among the plurality of vapor chamber (VC) case configurations;
determining whether the particular VC case configuration remedies all of the potential interfering locations; and
based at least on part on a positive determination that the particular VC case configuration remedies all of the potential interfering locations, electroforming the vapor chamber to form the vapor chamber case according to the particular VC case configuration, including rimless, seamless outer peripheral surfaces aligned and facing according to the particular case outer perimeter, and the other rimless, seamless lateral peripheral surfaces aligned and facing to form at least one clearance surface according to the particular one or more clearance perimeters.

17. The method of claim 16, further comprising:
upon a negative determination that the particular VC case configuration remedies all of the potential interfering locations:
determining a candidate modification of the particular VC case configuration that remedies all of the potential interfering locations,
determining a candidate modification of the configuration data that, in combination with the particular VC case configuration, remedies all of the potential interfering locations, and
computing an estimated cost of the candidate modification of the particular VC case configuration,
computing an estimated cost of the candidate modification of the configuration data, and
applying the candidate modification of the particular VC case implementation, or the candidate modification of the configuration data, or both, depending on a comparison of the estimated cost of the candidate modification of the configuration data, to the estimated cost of the candidate modification of the particular VC case configuration.

18. A method, comprising:
storing a configuration data, including
a printed circuit board (PCB) data, indicating a PCB dimension,
a vapor chamber (VC) case configuration data that defines, at least in part, a VC case outer perimeter,
a device data, identifying a package height of a heat-generating (HG) device supportable on the PCB,
a component data identifying a plurality of components supportable on the PCB, and respective heights of the components, and
a layout configuration data defining, at least in part, a PCB device location for the HG device, and PCB locations for the components;
determining a set of interfering locations, based at least in part on the PCB device location for the HG device, the PCB locations for the components, the package height of the HG device, and the VC case outer perimeter the device data;
upon the set of interfering components being a non-null set, determining a feasibility of updating the VC case configuration data, else proceeding to output the VC case configuration data for VC electroform fabrication, wherein determining the feasibility includes determining whether a clearance perimeter is feasible for interfering locations; and
upon a negative result of determining the feasibility, exiting the method, else updating the VC case configuration data to include a clearance perimeter surrounding each interfering location.

19. The method of claim 18, wherein:
determining the feasibility includes an iterative determination, each iteration including:
i) selecting at least one interfering location from the set of interfering locations,
ii) determining feasibility of adding another clearance perimeter to accommodate the least one interfering location, and
upon a negative result of determining the feasibility, exiting the method, else,
updating the VC case configuration data to include a clearance perimeter surrounding the interfering location associated with the iteration,
removing the interfering location from the set of interfering locations, and,
if the set of interfering locations is not null, returning to (i), else ending the method.

20. The method of claim 18, further comprising:
electroforming a vapor chamber, with a configuration for thermal coupling to the HG device, and including a vapor chamber case with rimless, seamless outer peripheral surfaces aligned and facing according to the VC case outer perimeter, wherein, upon the VC case configuration data including one or more clearance perimeters, the electroforming includes forming other rimless, seamless lateral peripheral surfaces aligned and facing to form a clearance according to each clearance perimeter.
